(19) United States
(12) Patent Application Publication
(10) Pub. No.: US 2026/0353564 A1
(43) Pub. Date: Nov. 5, 2026

(54) Multi-Chip Module and Chip

(71) Applicant: ALTERA CORPORATION, San Jose, CA (US)

(72) Inventors: Arch ZALIZNYAK, San Mateo, CA (US); Guang CHEN, Fremont, CA (US); Archanna SRINIVASAN, San Jose, CA (US)

(21) Appl. No.: 19/658,920

(22) Filed: Apr. 27, 2026

(30) Foreign Application Priority Data
Apr. 30, 2025 (DE) 102025116755.9

(51) Int. Cl. H05K 1/181

(52) U.S. Cl. CPC H05K 1/181; H05K 2201/10378; H05K 2201/10515

(57) ABSTRACT

A Multi-Chip Module (100) comprises a first chip (110a), a second chip (110b), and an interposer substrate (120) to connect the first chip (110a) and the second chip (110b). Reference circuitry (130) provides a reference for circuitry within at least one of the first chip (110a) or the second chip (110b). The reference circuitry (130) comprises at least one passive reference element (132a, …, 132f) and control circuitry (134a, …, 134d) for the passive reference element (132a, …, 132f). At least one of the passive reference element (132a, …, 132f) or the control circuitry (134a, …, 134d) is arranged within the interposer substrate (120).

### FIELD

The present disclosure relates generally to integrated circuits, such as processors and/or field-programmable gate arrays (FPGAs). More particularly, the present disclosure relates to programmable logic devices, such as field programmable gate arrays (FPGAs).

### BACKGROUND

Modern electronics, such as computers, portable devices, network routers, data centers, Internet-connected appliances, and more, tend to include at least one integrated circuit device. Integrated circuit devices may take on a variety of forms, including processors (e.g., central processing units (CPUs)), memory devices, and programmable devices (e.g., FPGA), to name only a few examples. The programmable devices, in particular, may include a programmable fabric of logic that may be programmed (e.g., configured) and reprogrammed (e.g., reconfigured) after manufacturing to provide a wide variety of functionality based on a circuit design.

### BRIEF DESCRIPTION OF THE FIGURES

Some examples of apparatuses and/or methods will be described in the following by way of example only, and with reference to the accompanying figures, in which

FIG. 1a is a schematic top view of an embodiment of a Multi-Chip Module;

FIG. 1b is a schematic top view of a further embodiment of a Multi-Chip Module;

FIG. 2 is an example of reference circuitry;

FIG. 3 is another example of reference circuitry;

FIG. 4 is a package‑level cross‑section of a chip;

FIG. 5 is a flow chart of a method to operate a multi-chip module of FIGS. 1a or 1b;

FIG. 6 is a block diagram of a system used to program an integrated circuit device;

FIG. 7 is a block diagram of an integrated circuit device;

FIG. 8 is a block diagram of an illustrative example of a configurable integrated circuit;

FIG. 9 is a block diagram of an illustrative example of a configurable integrated circuit;

FIG. 10 is a block diagram of a system that can be used to implement a circuit design to be programmed into a programmable logic device using design software;

FIG. 11 is a schematic cross section of a programmable logic device that includes fabric dies and base dies that are connected to one another via microbumps;

FIG. 12 is a block diagram illustrating a computing system; and

FIG. 13 is a block diagram of a data processing system.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e. only A, only B as well as A and B, unless expressly defined otherwise in the individual case. As an alternative wording for the same combinations, "at least one of A and B" or "A and/or B" may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms "include", "including", "comprise" and/or "comprising", when used, describe the presence of the specified features, integers, steps, operations, processes, elements, components and/or a group thereof, but do not exclude the presence or addition of one or more other features, integers, steps, operations, processes, elements, components and/or a group thereof.

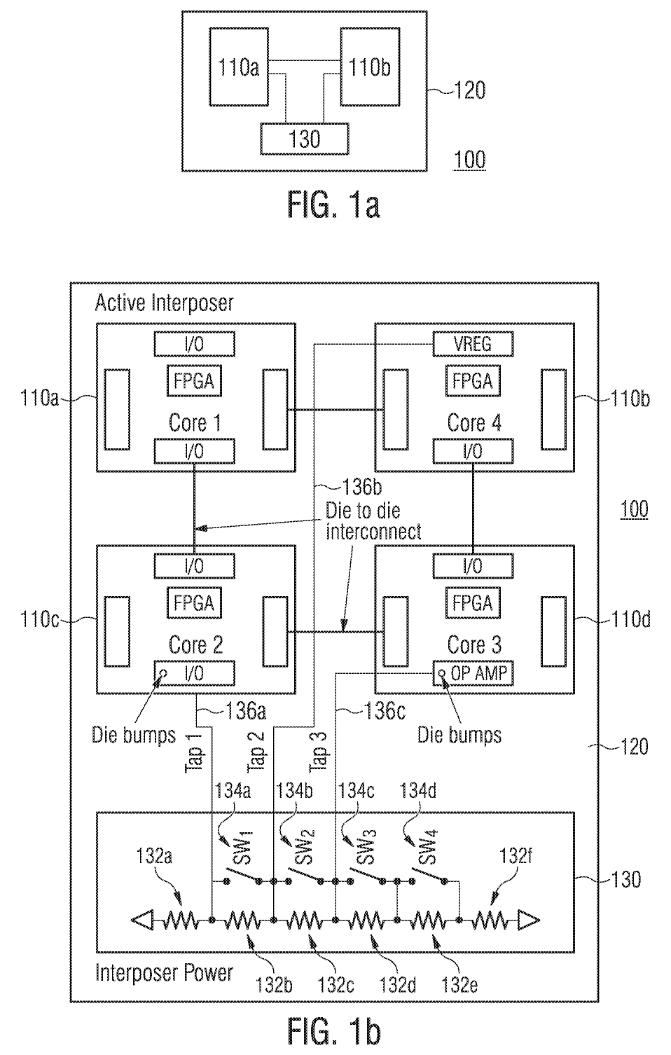

FIG. 1 is a schematic top view of an embodiment of a Multi-Chip Module 100.

The Multi-Chip Module 100 comprises a first chip 110a, a second chip 110b, and an interposer substrate 120 to connect the first chip 110a and the second chip 110b. Reference circuitry 130 generates a reference for circuitry within at least one of the first chip 110a or the second chip 110b. The reference circuitry 130 comprises at least one passive reference element and control circuitry for the passive reference element. At least one of the passive reference element or the control circuitry is arranged at the interposer substrate 120.

A reference can be understood as a standard or benchmark that establishes a point of comparison within a system. It represents a conceptual baseline against which other elements are measured or adjusted, ensuring consistency and stability. A reference is often implemented as a specific value or signal that serves to guide the operation of a circuit or system. This value, whether it be a voltage, current, or another measurable parameter, is used to calibrate or regulate the performance of associated components. It functions as an input that defines the operating conditions and sets the desired state for the system's proper functionality. A reference may be generated through a combination of precise functional and structural features that work in concert to produce a stable, known parameter. For example, a voltage reference might be constructed using a resistor network integrated at a package substrate, where the passive elements, such as specific resistors, are carefully selected and arranged to establish a fixed potential. This configuration may further be supported by control circuitry that can include components like vias, fuses, switches, or multiplexers, which enable the activation, deactivation, or fine-tuning of the reference under various operational conditions.

The reference elements may be formed or embedded within the interposer substrate or, likewise, be placed on top of the interposer substrate to arrange them at the interposer substrate. If something is said to be arranged at a substrate, it may be (partially) embedded within said substrate or placed on top of either side of said substrate.

Embedding resistors as reference elements in the substrate may, for example, be achieved using thin- or thick-film foil layers. A resistive ink or metal-alloy foil can be laminated between dielectric layers. During lamination it can be pressed and cured to form a uniform resistive sheet. Additionally, it may be laser-trimmed or patterned in the inner layers to precise values. Similarly, embedded resistor networks may be used. Prefabricated resistor chips or networks may be placed into milled cavities in the core, then overlaid with prepreg and copper. This may yield compact, tightly matched multi-resistor arrays hidden inside the board.

Alternatively, resistors may be mounted or printed on the surface of the interposer substrate.

Discrete SMD resistors (e.g. metal-film or thick-film chip resistors) may be soldered to copper pads. Screen-printed resistive pastes may be used. A polymer- or ceramic-based resistive ink may be silk-screened onto the board, then cured. It may additionally be laser-trimmed for tighter tolerances. Copper-trace resistors may be implemented by shaping a thin copper trace (long, narrow meander) on a high-impedance layer.

An interposer substrate 120 serves a specialized intermediate layer that facilitates the electrical and sometimes mechanical connection between multiple integrated circuits or chips within a multi-chip module or between a chip and a printed circuit board. In a single chip context, an interposer substrate 120 may also be called package substrate. It functions as a high-density interconnect platform, allowing for compact designs and may also improve signal integrity by reducing the distance that signals must travel. The interposer substrate 120 can be designed with precise routing features, including traces and vias, to manage power distribution and thermal dissipation.

A passive reference element is a component that serves as a stable benchmark or fixed point within an electronic system or within reference circuitry. It represents an inherent standard against which other signals or parameters can be compared, without actively altering its own state in response to external conditions. A passive reference element functions by maintaining a consistent value, such as a fixed resistance that serves as a foundational parameter for system calibration and operation. It is designed to provide a reliable reference point that supports the accurate functioning of circuits by offering a constant standard that other components can use for alignment and measurement. A passive reference element may comprise specifically chosen materials and structures that result in minimal variation under different operating conditions. For example, a resistor-based passive reference element may be fabricated using a resistor network, where the resistor values are precisely controlled during manufacturing to ensure a stable voltage drop or current flow. This element is inherently non-reactive, meaning it does not actively adjust its state but instead provides a fixed, predictable value that is crucial for calibrating active circuitry, ensuring signal integrity, and maintaining system performance also in the presence of temperature fluctuations and power supply variations.

Control circuitry for the passive reference element can be understood as a system of components designed to manage how the passive reference element is utilized within a larger electronic framework. This circuitry may serve as an intermediary that governs the behavior of the reference element, ensuring that it consistently fulfills its role as a benchmark within the system without itself being an active source of the reference signal. The control circuitry is responsible for regulating the engagement of the passive reference element, effectively determining when and how the element contributes to the overall performance of the circuit. It provides the means to enable or disable the reference element, thereby allowing for adjustments that can calibrate or fine-tune system parameters. The control circuitry for the passive reference element can be implemented with specific hardware components such as transistors, multiplexers, fuses, or dedicated switches, which are configured to dynamically control the connectivity and activation state of the passive reference element. This circuitry may reside on the same substrate as the passive reference element or be integrated within another integrated circuit, where it monitors external signals and environmental conditions to adjust the reference element’s contribution in real time. Through control logic and/or configurable settings, this circuitry ensures that the passive reference element remains effective in providing a stable and accurate reference point, thereby enhancing the overall performance and reliability of the electronic system.

The embodiments illustrated in FIGS. 1a and 1b offer significant advantages as compared to conventional solutions, which rely on reference compensation structures residing on the PCB and connecting to the chips or dies through lengthy PCB traces, package balls, and package traces. In these prior implementations, the calibration control circuits for the reference compensation structures were designed by the PCB designer, and the compensation structures themselves were included in the PCB list of materials. The extended connection paths in the prior art not only increase resistance and noise coupling, thereby reducing the accuracy of the reference signal, but also necessitate the use of additional package balls. This requirement resulted in larger package sizes, increased package costs, and an overall expanded form factor. Moreover, the added requirements on the PCB bill of materials and the extra design effort for calibration control circuits placed an additional burden on PCB designers.

Integrating at least one of the passive reference element or the control circuitry within the interposer substrate 120 addresses these issues directly. This integration minimizes the physical distances involved, thereby reducing resistance and noise coupling and enhancing the accuracy of the reference signal. The approach eliminates the need for extra package balls, leading to a more compact package and lower costs, while also simplifying the PCB bill of materials and relieving the PCB designer of additional calibration control circuitry design efforts.

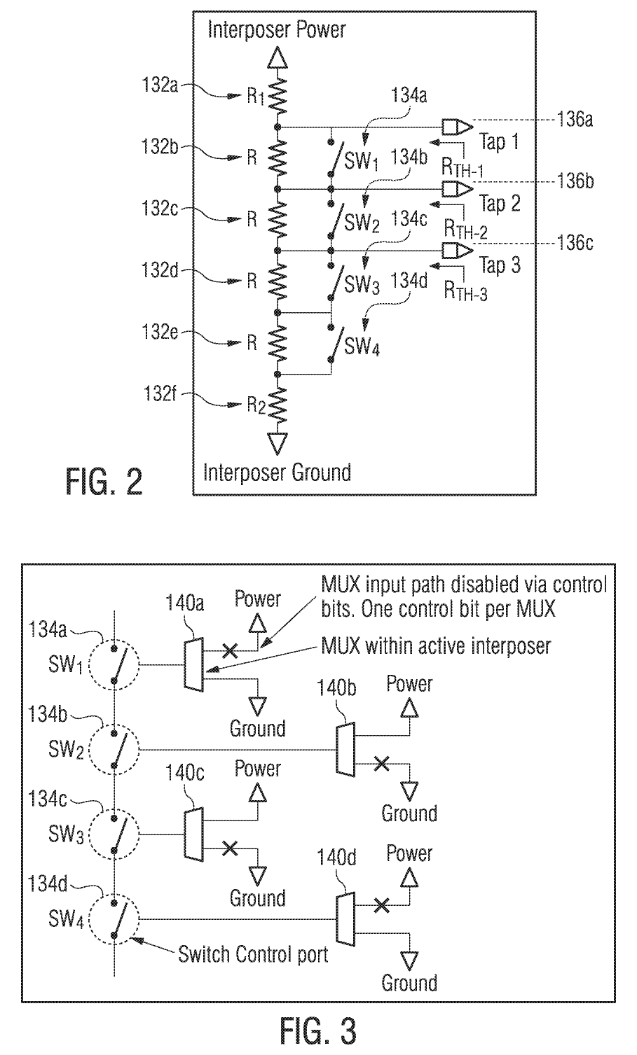

The embodiment of FIG. 2 illustrates another exemplary implementation where four chips 110a, 110b, 110c, and 110d are placed on an interposer substrate 120 that connects the chips 110a, …, 110d with one another. The chips are Field-Programmable Gate Arrays (FPGAs) and the reference circuitry 130 comprises six serially connected resistances 132a, …, 132f that serve as passive reference elements. Utilizing resistances as the passive reference elements may, for example, allow for a precise control of reference voltage levels required for consistent performance of the chips 110a, …, 110d.

Switches 134a to 134d are part of the control circuitry to selectively provide a reference to chips 110b to 110d via signal lines 136a, 136b, and 136c routed within the interposer substrate. Switches 134a to 134c are also implemented within the interposer substrate 120. Since switches are active elements in the sense that they may exhibit at least two different states, interposer substrate 120 can also be called an active interposer. An active interposer substrate 120 is a type of interconnect substrate that not only routes signals between various chips but also includes integrated active components, such as amplifiers, signal conditioners, or switches. This means that rather than serving solely as a passive medium for electrical connections, an active interposer can perform additional functions like boosting signal strength, filtering noise, or dynamically managing power distribution. By incorporating these active elements, the interposer may enable more complex electronic systems.

Depending on the implementation, active or passive interposer substrates can be used and the functionality within the reference circuitry can be distributed arbitrarily between the interposer substrate 120 and one or more of the chips 110a and 110b.

As illustrated in FIG. 1b, the passive reference elements may be arranged at the interposer substrate 120 for both active and passive interposers. This arrangement places the passive reference components directly at the interposer substrate 120, facilitating closer integration with the connecting pathways between the first and second chips 110a and 110b. By embedding the passive reference elements132a, …, 132f at the interposer substrate 120, the Multi-Chip Module 100 (MCM) benefits from reduced signal transmission distances and minimized interference, which enhances the precision of reference signals and improves the overall efficiency of the Multi-Chip Module 100.

For passive interposers, the control circuitry 130 can be included in one or more of the chips 110a, 110d.

Alternatively, the resistances 132a, …, 132f (precision reference structures forming or being part of the passive reference element) can be implemented at the package substrate of one or more of chips 110a, …, 110d with the control circuitry 130 generating calibration controls being in the interposer substrate 120.

Alternatively, and in the event of an active interposer 120, the control circuitry for dynamic and/or static programming or control of the passive reference elements for the FPGAs can be employed at the interposer substrate 120 to control use of the precision Reference/Compensation structure for calibration.

In other words, the control circuitry 130 of some embodiments is arranged within at least one of the first chip 110a or the second chip 110b. Placement of the control circuitry 130 within one of the chips allows for direct management of the passive reference elements associated with that chip. Integrating control circuitry into the chips may lead to faster response times and more efficient control mechanisms, thereby optimizing the performance and adaptability of the reference circuitry within the Multi-Chip Module.

According to some embodiments, the control circuitry 13 is arranged at the interposer substrate 120. Hosting the control circuitry at the interposer substrate centralizes the management of passive reference elements, which may streamline the coordination between the first and second chips. This arrangement may lead to more efficient control operations and easier integration of additional reference elements, enhancing the scalability and flexibility of the Multi-Chip Module for various applications.

According to some embodiments, the control circuitry 130 may alternatively or additionally comprise vias or fuses to enable or disable passive reference elements. Incorporating vias or fuses within the control circuitry allows for the selective activation or deactivation of passive reference elements. This capability provides the embodiments with the flexibility to adjust reference settings dynamically, accommodating different operational modes or compensating for component variations. As a result, the Multi-Chip Module can maintain optimal performance under varying conditions, increasing its reliability and adaptability.

According to some embodiments, the control circuitry 130 can be dynamically reconfigurable. This may allow the control circuitry to adjust its configuration in real-time based on changing operational requirements or environmental conditions, for example, if a specific function in an FPGA or chip 110a, …., 110d is requested, activated or configured. Dynamic reconfiguration enhances the adaptability of the reference circuitry, enabling the Multi-Chip Module to maintain reference signals even as system demands fluctuate. Programming and dynamic reconfiguration may, for example, be performed through configuration bit (CRAM) enablement by device or chip firmware/ QII to program a setting.

For example, multiplexers can be set up or programmed to determine the calibration settings through several methods. One method may be using configuration bits stored in CRAM, which are temporary memory settings that enable the multiplexer functions. Another method involves using fuse bits, which are one-time programmable settings that permanently configure the multiplexers. Alternatively, the calibration settings can be programmed through firmware or via a QII interface, allowing the system to adjust these settings through software.

A QII interface is a dedicated communication channel or programming interface that allows firmware or software to configure and adjust the calibration settings of the device. It serves as an alternative pathway to using configuration bits stored in CRAM or one-time programmable fuse bits, enabling dynamic programming of the multiplexer control settings. Essentially, the QII interface provides a means for the system to receive and apply calibration parameters, ensuring that the reference circuitry operates according to the desired specifications during initialization or runtime.

FIG. 2 illustrates the control circuitry of FIG. 1b in isolation. As already elaborated on before, switches 134a to 134d serve to selectively couple the signal lines 136a, 136b, and 136c to the resistances 132a, …, 132f to provide reference voltage to chips 110b, 110c, and 110d. Further embodiments may also use different control circuitry comprising at least one switch coupled to a passive reference element. Integrating a switch within the control circuitry allows for precise and dynamic control over the activation state of the passive reference elements. This setup enables the module to selectively manage reference signals, turning elements on or off as needed to optimize performance. By providing such granular control, the Multi-Chip Module can enhance its efficiency and responsiveness, ensuring that reference signals remain consistent and reliable under various operational conditions.

The switch may also be arranged in the first chip or in the second chip. Positioning the switch within either the first or second chip allows for localized control of reference elements associated with that specific chip. This placement may lead to more efficient signal routing and reduced latency in controlling reference states.

In summary, FIG. 2 illustrates a Reference Compensation (R_{comp}) structure, also known as “Resistor stack," on an Interposer with multiple taps. These taps can provide reference signals to various circuits on a core die, such as op-amps, voltage regulators, and bandgaps, or to circuits within multiple cores in the MCM. The "Resistor stack" can also be implemented in the Package substrate. Each tap has a different voltage level controlled by Switches 1 to 4 (SW1-SW4). The Calibration control circuitry manages these switches and is in the Active or Passive interposer or the FPGA core die.

FIG. 3 illustrates how the switches can be controlled in a practical implementation.

The control circuitry includes multiplexers 140a, 140b, 140c, and 140d that govern the operation of associated switches 134a, 134b, 134c, and 134d, thereby managing the connection of the passive reference elements within the reference circuitry.

The components interact such that the control circuitry, through multiplexers 140a, 140b, 140c, and 140d, directly influences the state of the switches connected to the passive reference elements. When a multiplexer selects a connection to either the power rail or to ground, the corresponding switch is driven into a closed state. This deliberate configuration integrates the specific passive reference element—whether 132a, 132b, 132c, 132d, 132e, or 132f—into the active reference network. The selective closing of the switches ensures that only the desired passive reference elements contribute to the reference signal, thereby enabling precise control over the resulting reference voltage.

Through this dynamic interaction, the interposer substrate 120 provides a range of reference voltages to first chip 110a and second chip 110b. By utilizing multiplexers 140, 140b, 140c, and 140d to control the switches and, in turn, the incorporation of the passive reference elements into the reference circuitry 130, the system can adjust the overall resistance and voltage levels.

In other words, some embodiments of control circuitry comprise at least one multiplexer coupled to the switch to control the switch. The inclusion of a multiplexer in the control circuitry facilitates the selection and management of switches connected to passive reference elements. This arrangement allows for a flexible control scheme, enabling the module to handle multiple reference signals simultaneously or switch between different reference configurations as needed.

Furthermore, a practical implementation of multiplexers illustrated in FIG. 3 may incorporate fuses or vias that function as a diplexer. These elements are designed to be activated only once during production, providing a one-time programmable mechanism to permanently select or disable specific passive reference elements. By serving as a diplexer, the fuses or vias offer a robust and irreversible method for fine-tuning the reference circuitry during manufacturing, ensuring that the final configuration meets the desired calibration and performance criteria while minimizing parasitic effects and noise coupling.

In summary, FIG. 3 illustrates control circuitry, also known as calibration control circuitry. It consists of sets of 2-input multiplexers (MUXs) and switches that may be built into the active interposer. Alternatively, the calibration control circuit consists of sets of 2-input MUXs and switches that reside on an FPGA core die. One MUX controls one switch. Power and ground connect to a MUX input to provide either a logic 1 or logic 0 MUX output. The MUX output is referred to as a calibration setting. The calibration setting is wired to a control port of a switch that it controls. A MUX can be programmed to output either logic 1 or logic 0 based on the desired state of the corresponding switch. The programming wire, or MUX setting, comes from the CRAM FPGA bit on die to control MUX output. The control circuit can also adjust the generated reference signal to compensate for other attributes that affect the circuit's overall accuracy, such as temperature variation.

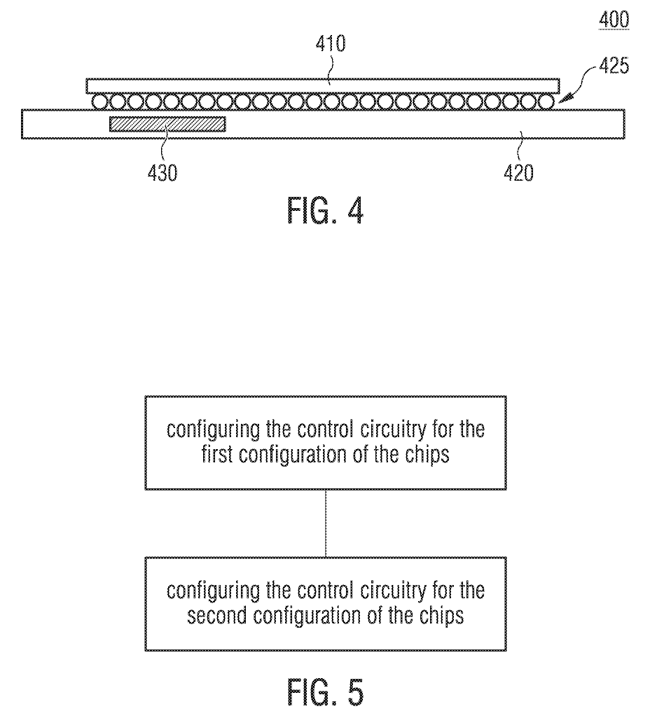

FIG. 4 illustrates an embodiment of a chip 400 where the functionality previously described for the interposer substrate 120 of a MCM can be integrated into a package substrate 420. The reference circuitry 430 for the chip 400 comprises a resistor assembly comprising at least a first resistance 132a and a second resistance 132b and corresponding control circuitry.

FIG. 4 is a simplified cross-sectional package level view of chip 400, illustrating at a high level how die 410 is mounted on package substrate 420 using solder bumps 425. Reference circuitry 430 is at least partially located at the package substrate 420, thereby indicating that at least the resistor assembly or the control circuitry resides in the package substrate 430. The figure abstractly demonstrates that the package substrate 420 is not just a mechanical or interconnection layer but can incorporate functional components—for example the passive resistor assembly that can provide at least two references for the die 410 while the control circuitry for the resistor assembly resides within the die 410.

This design integrates reference components into the package substrate, ensuring stable reference signals for the die's circuitry. By embedding reference elements within the package substrate, the chip achieves enhanced performance consistency and reduces potential signal interference, thereby improving the reliability and efficiency of the chip's operations.

According to some embodiments, the die 410 can implement functionality of a Field-Programmable Gate Array. By utilizing a Field-Programmable Gate Array (FPGA) within the die, the chip gains enhanced flexibility and reconfigurability in its processing capabilities. This functionality allows the chip to be programmed and reprogrammed for various applications and tasks, making it highly adaptable to different operational requirements. Consequently, the chip can be customized to perform specific functions as needed, increasing its versatility and applicability in a wide range of electronic systems.

The previously described embodiments involve placing Passive or Active Reference Compensation (Rcomp) structures in an interposer. A single R_{comp} structure with multiple taps can serve various circuits like op-amps, voltage regulators, and bandgaps on a single die or multiple FPGA cores in an MCM. Introducing Partial and Statically/Dynamically Reprogrammable Calibration control in the interposer is proposed. Calibration control can be configured through bit enablement, fuse bits, or firmware programming. Metal-mask-customized programming can be done via metal connection enablement in the Passive interposer. An alternative is placing R_{comp} structures in the package substrate for mono devices. The approach eliminates impedance/resistance variation and noise from long connection traces affecting calibration accuracy. It reduces package size and cost by eliminating the need for extra package balls and removes added PCB Bill of Materials requirements for customers. The design efforts for Calibration circuits and R_{comp} structures are simplified, enhancing user experience. Furthermore, it allows for metal-mask customization in the Passive interposer, reducing development costs. Dynamic reconfiguration in Active interposers changes Calibration settings without requiring PCB respins. Configuration Modes for Active Interposer include Partial Reconfiguration and Dynamic Reconfiguration. For the Passive Interposer, Partial Reconfiguration is possible. CRAM programming is used for Active Interposer while Fuse Bit Programming is available for both Active and Passive Interposers. Via/Metal programming is specific to the Passive Interposer.

FIG. 5 is a flow chart of a method to operate a multi-chip module of FIGS. 1a or 1b or a chip of FIG. 4 to dynamically reconfigure the use of reference structures and to change the references provided by them.

The method comprises configuring (510) the control circuitry to use the at least one passive reference element in a first setting if the first chip 110a and the second chip 110b or the chip 400 are used in a first configuration.

The method further comprises configuring (520) the control circuitry to use the at least one passive reference element in a second setting if the first chip 110a and the second chip 110b or the chip 400 are used in a second configuration.

As illustrated by means of the flow chart of FIG. 5, the embodiments described herein allow to dynamically adjust how the reference circuitry is used based on the configuration of the chips. Essentially, when the first chip 110a and the second chip 110b are arranged in a first configuration, the control circuitry is set to operate the passive reference in a first mode, which provides a specific reference condition suitable for that configuration. Conversely, when the chips are used in a second configuration, the control circuitry is reconfigured to utilize the passive reference elements in a second mode, thereby establishing an alternate reference condition that better suits the different operational setup. In this way, the method ensures that the multi-chip module adapts its calibration and reference settings to optimize performance based on the configuration of its constituent chips.

For example, in a reconfigurable FPGA, the first configuration might be tailored for high-speed, computationally intensive functions such as digital signal processing or high-frequency data acquisition. In this scenario, the FPGA is programmed to utilize its high-performance logic blocks and specialized DSP slices. Consequently, the control circuitry is configured to select a set of passive reference elements that provide a low-noise, highly stable reference voltage. This reference is critical for maintaining signal integrity and precise timing, ensuring that the FPGA's high-speed transceivers and processing elements operate reliably under demanding performance conditions.

Conversely, the second configuration could be employed when the FPGA is repurposed for functions that are more power-efficient or require a different operational mode, such as implementing a microcontroller or managing lower-speed peripheral interfaces. In this mode, the FPGA might deactivate or repurpose some of its high-performance resources to reduce power consumption and thermal output. The control circuitry, in turn, is reconfigured to select an alternate set of passive reference elements that provide a reference voltage optimized for lower power consumption and potentially a wider tolerance range. This change in reference conditions supports a more relaxed timing environment and accommodates the reallocated resources within the FPGA, ensuring reliable operation in energy-efficient applications.

Furthermore, another scenario could involve dynamically altering specific functional blocks within the FPGA. For instance, if certain portions of the FPGA are reconfigured to implement different algorithms or to change operating frequencies, the reference voltage required by these blocks may differ. The control circuitry can adjust the reference by selecting appropriate passive reference elements that correspond to the new operational mode. This flexibility allows the FPGA to seamlessly transition between various configurations—whether shifting from high-speed data processing to low-power control functions or adjusting the reference voltage to suit different algorithmic requirements—ensuring optimal performance and efficiency across a broad range of applications.

In some embodiments, the control circuitry for the second configuration reconfigures only the use of a subset of passive reference elements that are required to provide different reference values in the second configuration, while remaining passive reference elements remain unaltered.

By reconfiguring only the subset of passive reference elements that are required to provide different reference values, the design minimizes changes to the overall reference circuitry, thereby preserving the stability and accuracy of the elements that do not need alteration. This selective reconfiguration may reduce the risk of introducing errors or additional noise, as fewer components are disturbed during the transition between configurations. It also simplifies the design and calibration process, as the control circuitry only needs to adjust the essential parts of the reference network, which can lead to improved reliability and more predictable performance.

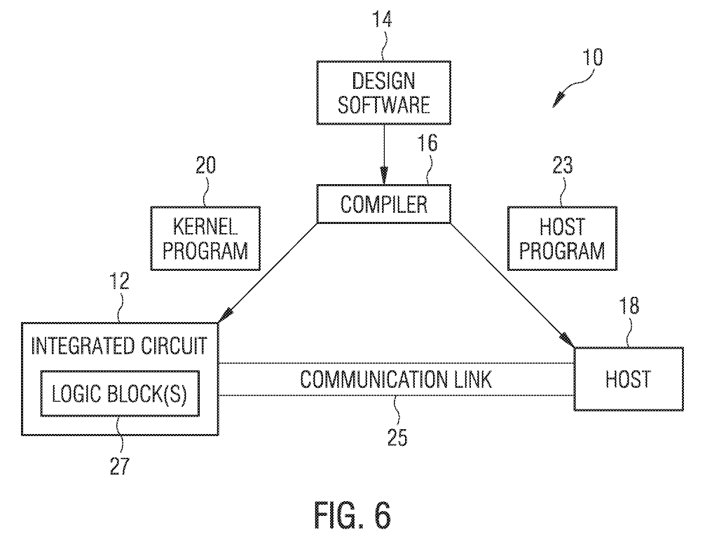

FIG. 6 illustrates a block diagram of a system 10 that may implement one or more functionalities. For example, a designer may desire to implement functionality, such as the operations of this disclosure, on an integrated circuit device 12 (e.g., a programmable logic device, such as a field programmable gate array (FPGA) or an application specific integrated circuit (ASIC)). In some cases, the designer may specify a high-level program to be implemented, such as an OpenCL^{TM} program or SYCL^{TM}, which may enable the designer to more efficiently and easily provide programming instructions to configure a set of programmable logic cells for the integrated circuit device 12 without specific knowledge of low-level hardware description languages (e.g., Verilog or VHDL). For example, since OpenCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

The designer may implement high-level designs using design software 14, such as a version of Altera® Quartus® by Altera Corporation. The design software 14 may use a compiler 16 to convert the high-level program into a lower-level description. In some embodiments, the compiler 16 and the design software 14 may be packaged into a single software application. The compiler 16 may provide machine-readable instructions representative of the high-level program to a host 18 and the integrated circuit device 12. The host 18 may receive a host program 23 which may be implemented by the kernel programs 20. To implement the host program 23, the host 18 may communicate instructions from the host program 23 to the integrated circuit device 12 via a communications link 25, which may be, for example, direct memory access (DMA) communications or peripheral component interconnect express (PCIe) communications. In some embodiments, the kernel programs 20 and the host 18 may enable configuration of a logic block 27 on the integrated circuit device 12. The logic block 27 may include circuitry and/or other logic elements and may be configured to implement arithmetic operations, such as addition and multiplication.

The designer may use the design software 14 to generate and/or to specify a low-level program, such as the low-level hardware description languages described above. For example, the design software 14 may be used to map a workload to one or more routing resources of the integrated circuit device 12 based on a timing, a wire usage, a logic utilization, and/or a routability. Additionally, or alternatively, the design software 14 may be used to route first data to a portion of the integrated circuit device 12 and route second data, power, and clock signals to a second portion of the integrated circuit device 12. Further, in some embodiments, the system 10 may be implemented without a host program 23 and/or without a separate host program 23. Moreover, in some embodiments, the techniques described herein may be implemented in circuitry as a non-programmable circuit design. Thus, examples described herein are intended to be illustrative and not limiting.

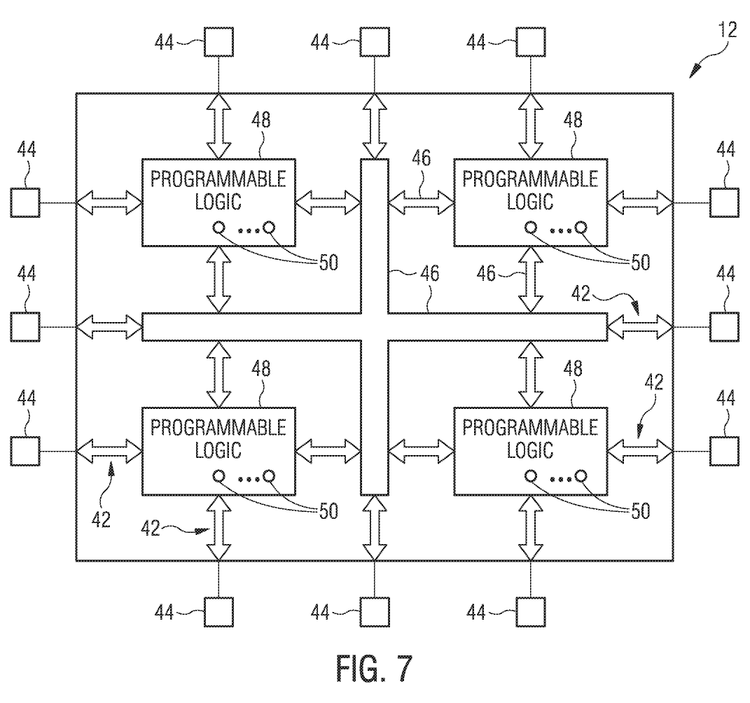

Turning now to a more detailed discussion of the integrated circuit device 12, FIG. 7 is a block diagram of an example of the integrated circuit device 12 as a programmable logic device, such as a field-programmable gate array (FPGA). Further, it should be understood that the integrated circuit device 12 may be any other suitable type of programmable logic device (e.g., a structured ASIC such as eASIC™ by Altera Corporation ASIC and/or application-specific standard product). The integrated circuit device 12 may have input/output circuitry 42 for driving signals off the device and for receiving signals from other devices via input/output pins 44. Interconnection resources 46, such as global and local vertical and horizontal conductive lines and buses, and/or configuration resources (e.g., hardwired couplings, logical couplings not implemented by designer logic), may be used to route signals on integrated circuit device 12. Additionally, interconnection resources 46 may include fixed interconnects (conductive lines) and programmable interconnects (i.e., programmable connections between respective fixed interconnects). For example, the interconnection resources 46 may be used to route signals, such as clock or data signals, through the integrated circuit device 12. Additionally, or alternatively, the interconnection resources 46 may be used to route power (e.g., voltage) through the integrated circuit device 12. Programmable logic 48 may include combinational and sequential logic circuitry. For example, programmable logic 48 may include look-up tables, registers, and multiplexers. In various embodiments, the programmable logic 48 may be configured to perform a custom logic function. The programmable interconnects associated with interconnection resources may be considered to be a part of programmable logic 48.

Programmable logic devices, such as the integrated circuit device 12, may include programmable elements 50 with the programmable logic 48. In some embodiments, at least some of the programmable elements 50 may be grouped into logic array blocks (LABs). As discussed above, a designer (e.g., a user, a customer) may (re)program (e.g., (re)configure) the programmable logic 48 to perform one or more desired functions. By way of example, some programmable logic devices may be programmed or reprogrammed by configuring programmable elements 50 using mask programming arrangements, which is performed during semiconductor manufacturing. Other programmable logic devices are configured after semiconductor fabrication operations have been completed, such as by using electrical programming or laser programming to program the programmable elements 50. In general, programmable elements 50 may be based on any suitable programmable technology, such as fuses, anti-fuses, electrically programmable read-only-memory technology, random-access memory cells, mask-programmed elements, and so forth.

Many programmable logic devices are electrically programmed. With electrical programming arrangements, the programmable elements 50 may be formed from one or more memory cells. For example, during programming, configuration data is loaded into the memory cells using input/output pins 44 and input/output circuitry 42. In one embodiment, the memory cells may be implemented as random-access-memory (RAM) cells. The use of memory cells based on RAM technology as described herein is intended to be only one example. Further, since these RAM cells are loaded with configuration data during programming, they are sometimes referred to as configuration RAM cells (CRAM). These memory cells may each provide a corresponding static control output signal that controls the state of an associated logic component in programmable logic 48. In some embodiments, the output signals may be applied to the gates of metal-oxide-semiconductor (MOS) transistors, fin field effect transistors (FinFET), or gate-all-around (GAA) transistors within the programmable logic 48.

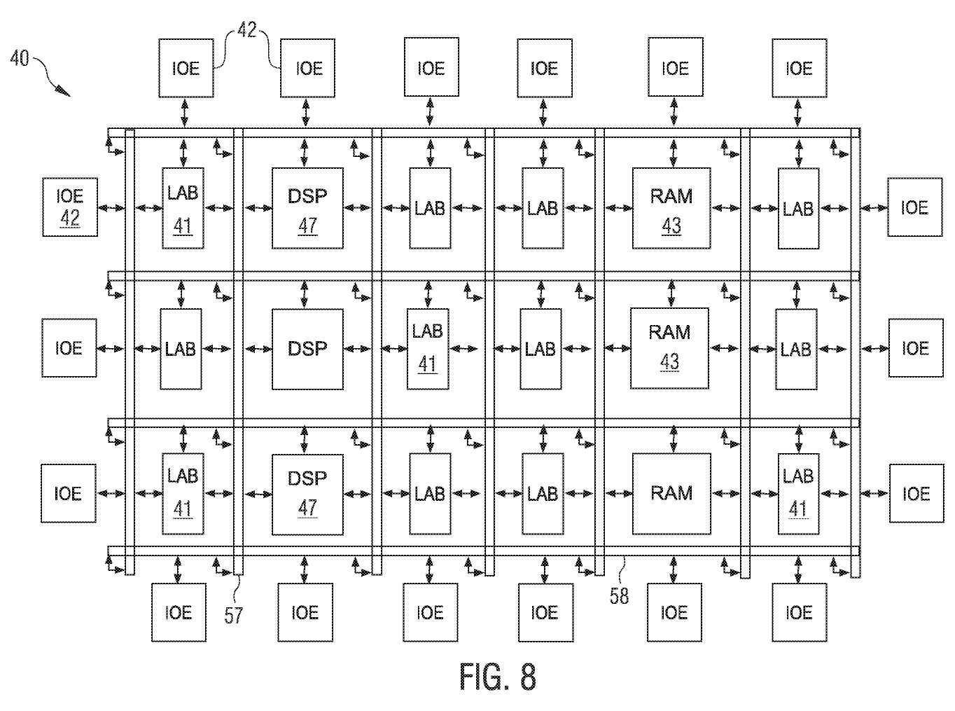

FIG. 8 is a diagram of an illustrative example of a configurable integrated circuit (IC) 40, for example the integrated circuit device of one of the FIGS. 5, 6, 9, 10, 11 and/or 12. As shown in FIG. 8, the configurable integrated circuit 40 includes a two-dimensional array of configurable logic circuit blocks, including logic array blocks (LABs) 41 and other configurable logic circuit blocks, such as random access memory (RAM) blocks 43 and digital signal processing (DSP) blocks 47, for example. Configurable logic circuit blocks, such as LABs 41, can include smaller configurable regions (e.g., configurable logic elements, configurable logic blocks, or adaptive logic modules (ALMs)) that receive input signals and perform custom functions on the input signals to produce output signals.

The configurable integrated circuit 40 also includes programmable interconnect circuitry in the form of vertical routing channels 57 (i.e., interconnects formed along a vertical axis of configurable integrated circuit 40) and horizontal routing channels 58 (i.e., interconnects formed along a horizontal axis of configurable integrated circuit 40), each routing channel including at least one track to route at least one wire. One or more of the routing channels 57 and/or 58 can be part of a network-on-chip (NOC) having router circuits.

In addition, the configurable integrated circuit 40 has input/output elements (IOEs) 42 for driving signals off of configurable integrated circuit 40 and for receiving signals from other devices. Input/output elements 42 can include parallel input/output circuitry, serial data transceiver circuitry, differential receiver and transmitter circuitry, or other circuitry used to connect one integrated circuit to another integrated circuit. Input/output elements 42 can include general purpose input/output (GPIO) circuitry (e.g., on the top and bottoms edges of IC 40), high-speed input/output (HSIO) circuitry (e.g., on the left edge of IC 40), and on-package input/output (OPIOs) circuitry (e.g., on the right edge of IC 40).

As shown, input/output elements 42 can be located around the periphery of the IC. If desired, the configurable integrated circuit 40 can have input/output elements 42 arranged in different ways. For example, input/output elements 42 can form one or more columns of input/output elements that can be located anywhere on the configurable integrated circuit 40 (e.g., distributed evenly across the width of the configurable integrated circuit). If desired, input/output elements 42 can form one or more rows of input/output elements (e.g., distributed across the height of the configurable integrated circuit). Alternatively, input/output elements 42 can form islands of input/output elements that can be distributed over the surface of the configurable integrated circuit 40 or clustered in selected areas.

Note that other routing topologies, besides the topology of the interconnect circuitry depicted in FIG. 8, can be used. For example, the routing topology can include wires that travel diagonally or that travel horizontally and vertically along different parts of their extent as well as wires that are perpendicular to the device plane in the case of three dimensional integrated circuits, and the driver of a wire can be located at a different point than one end of a wire. The routing topology can include global wires that span substantially all of configurable integrated circuit 40, fractional global wires such as wires that span part of configurable integrated circuit 40, staggered wires of a particular length, smaller local wires, or any other suitable interconnection resource arrangement.

Furthermore, it should be understood that examples disclosed herein may be implemented in any type of integrated circuit. If desired, the functional blocks of such an integrated circuit can be arranged in more levels or layers in which multiple functional blocks are interconnected to form still larger blocks. Other device arrangements can use functional blocks that are not arranged in rows and columns.

Configurable integrated circuit 40 can also contain programmable memory elements. The memory elements can be loaded with configuration data (also called programming data) using input/output elements (IOEs) 42. Once loaded, the memory elements each provide a corresponding static control signal that controls the operation of an associated functional block (e.g., LABs 41, DSP 47, RAM 43, or input/output elements 42).

In an exemplary scenario, the outputs of the loaded memory elements are applied to the gates of field-effect transistors in a functional block to turn certain transistors on or off and thereby configure the logic in the functional block including the routing paths. Programmable logic circuit elements that are controlled in this way include parts of multiplexers (e.g., multiplexers used for forming routing paths in interconnect circuits), look-up tables, logic arrays, AND, OR, NAND, and NOR logic gates, pass gates, etc.

The memory elements can use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory or programmable memory elements.

The programmable memory elements can be organized in a configuration memory array consisting of rows and columns. A data register that spans across all columns and an address register that spans across all rows can receive configuration data. The configuration data can be shifted onto the data register. When the appropriate address register is asserted, the data register writes the configuration data to the configuration memory elements of the row that was designated by the address register.

Configurable integrated circuit 40 can include configuration memory that is organized in sectors, whereby a sector can include the configuration bits that specify the function and/or interconnections of the subcomponents and wires in or crossing that sector. Each sector can include separate data and address registers.

The configurable IC 40 of FIG. 8 is merely one example of an IC that can be used with embodiments disclosed herein. The embodiments disclosed herein can be used with any suitable electronic integrated circuit or system. For example, the embodiments disclosed herein can be used with numerous types of electronic devices such as processor integrated circuits, central processing units, memory integrated circuits, graphics processing unit (GPU) integrated circuits, application specific standard products (ASSPs), application specific integrated circuits (ASICs), and configurable logic integrated circuits. Examples of configurable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

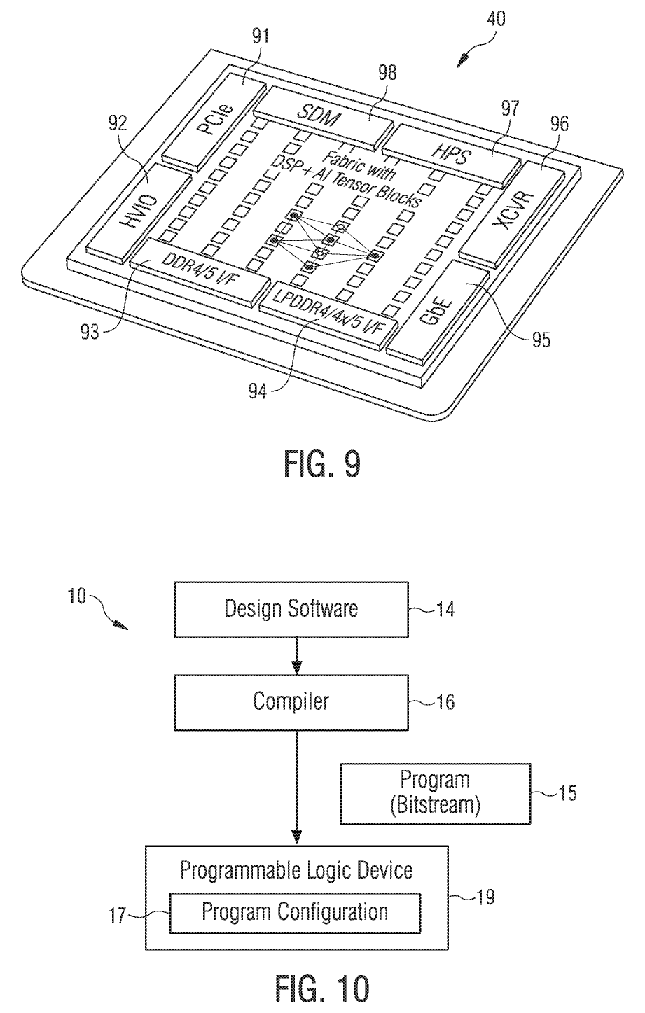

FIG. 9 is a block diagram of an example of a configurable integrated circuit (IC) 40, for example the integrated circuit device of one of the FIGS. 5, 6, 9, 10, 11 and/or 12. FIG. 9 may show also one or more components, which can be added to the configurable integrated circuit (IC) 40 of FIG. 8. The configurable integrated circuit (IC) 40 comprises components to enhance the device's performance and/or versatility. A High-Speed Serial Interface (HSSI) may include Physical Medium Attachment (PMA) banks that provide primary interfaces to physical channels, enabling rapid data transmission. Forward Error Correction (FEC) units may implement error correction codes to ensure data integrity during transmission. Physical Coding Sublayer (PCS) units may handle encoding, decoding, and word alignment, preparing data for processing (e.g. by FPGA cores). Additionally, there may be components with integrated support for protocols such as PCI Express (PCIe) 91 and/or Ethernet (e.g. Gigabit Ethernet GbE) 95, facilitating efficient and/or reliable connectivity.

General Purpose I/Os (GPIOs) may be divided into High-Speed I/Os (HSIO), which support one or more standards (e.g. single-ended low-voltage CMOS, pseudo-LVDS, MIPI D-PHY v2.5, and/or SGMII (LVDS)), making them suitable for applications requiring fast data exchange. The High-Voltage I/Os (HVIO) 92 may support higher voltage levels (e.g. ranging from 1.8V to 3.3V), ensuring compatibility with legacy systems and offering greater application flexibility.

The Hard Processor System (HPS) 97 may feature single or multicore processor subsystems providing robust processing capabilities for complex computations and system management. It may be equipped with dedicated interfaces and memory controllers to efficiently manage data flow between the processor and other system components.

For example, a Variable-Precision DSP with AI Tensor Blocks may include enhanced Digital Signal Processing (DSP) blocks capable of variable precision operations, including AI tensor computations, making the FPGA suitable for artificial intelligence and machine learning applications.

High Bandwidth Memory (HBM) blocks and/or embedded memory blocks may be designed for larger memory configurations, supporting various data widths and/or featuring hard Error Correction Code (ECC) functionality. Integrated memory interfaces may support various standards (e.g. DDR4/5 interface 93 and/or LPDDR4/4x/5 interface 94).

A transceiver (XCVR) 96 may support high data rates and feature advanced adaptive equalization circuits to maintain signal integrity over long distances.

A Secure Device Manager (SDM) 98 may manage device configuration, ensuring secure boot processes, authentication, and/or protection against tampering, thereby enhancing system security.

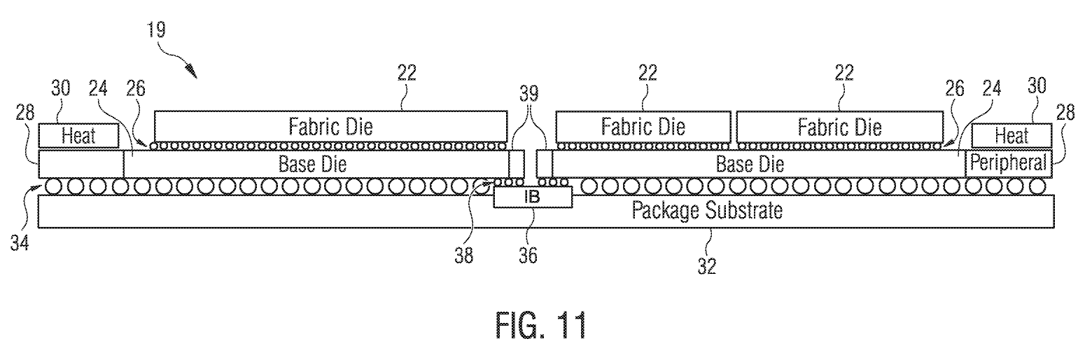

FIG. 10 illustrates a block diagram of a system 10 that can be used to implement a circuit design to be programmed onto a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 15, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 15 that describe the hardware implementations that should be stored in the programmable logic device 19. A program (bitstream) 15 can be programmed into the programmable logic device 19 as a configuration program 17. The configuration program 17 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 11, but many others can be used, and it should be understood that this disclosure is intended to encompass any suitable programmable logic device where programmable logic fabric and fabric support circuitry are at least partially separated on different integrated circuit die.

FIG. 11 is a diagram that depicts an example of the programmable logic device 19 that includes three fabric die 22 and two base die 24 that are connected to one another via microbumps 26. In the example of FIG. 11, at least some of the programmable logic fabric of the programmable logic device 19 is in the three fabric die 22, and at least some of the fabric support circuitry that operates the programmable logic fabric is in the two base die 24. For example, some of the circuitry of configurable IC 40 shown in FIG. 8 (e.g., LABs 41, DSP 47, and RAM 43) can be located in the fabric die 22 and some of the circuitry of IC 40 (e.g., input/output elements 42) can be located in the base die 24.

Although the fabric die 22 and base die 24 appear in a one-to-one relationship or a two-to-one relationship in FIG. 11, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 11, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

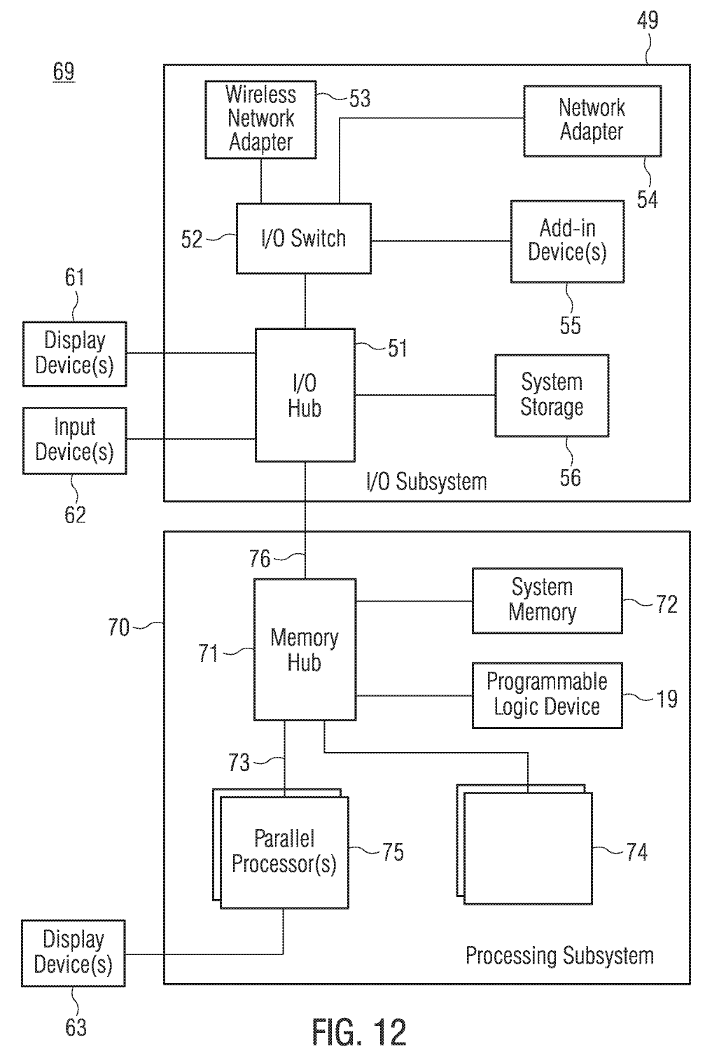

FIG. 12 is a block diagram illustrating a computing system 69 configured to implement one or more aspects of the embodiments described herein. The computing system 69 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 49 via a communication link 76. The I/O subsystem 49 includes an input/output (I/O) hub 51 that can enable the computing system 69 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 49, a system storage unit 56 can connect to the I/O hub 51 to provide a storage mechanism for the computing system 69. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 69 can include other components not shown in FIG. 12, including other port connections, optical storage drives, video capture devices, and the like, that can also be connected to the I/O hub 51. Communication paths interconnecting the various components in FIG. 12 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 69 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 69 can be integrated into a single package to form a system in package (SIP) configuration. In one embodiment, at least a portion of the components of the computing system 69 can be integrated into a multi-chip module (MCM), which can be interconnected with other multi-chip modules into a modular computing system.

The computing system 69 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 69. For example, any number of add-in cards or peripherals can be supported, or some components can be eliminated. Furthermore, some architectures can use different terminology for components similar to those illustrated in FIG. 12. For example, the memory hub 71 can be referred to as a Northbridge in some architectures, while the I/O hub 51 can be referred to as a Southbridge.

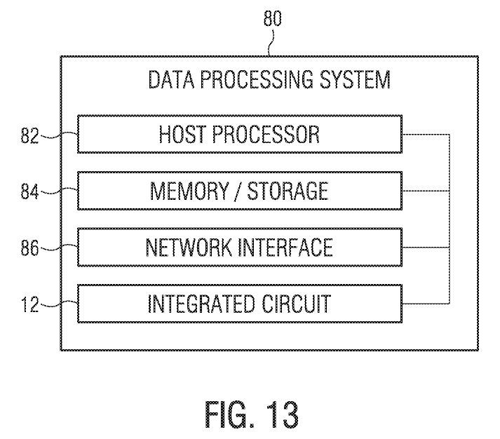

The integrated circuit device 12 may be a component included in a data processing system, such as a data processing system 80, shown in FIG. 13. The data processing system 80 may include the integrated circuit device 12 (e.g., a programmable logic device), a host processor 82 (e.g., a processor), memory and/or storage circuitry 84, and a network interface 86. The data processing system 80 may include more or fewer components (e.g., electronic display, designer interface structures, ASICs). Moreover, any of the circuit components depicted in FIG. 13 may include integrated circuits (e.g., integrated circuit device 12). The host processor 82 may include any of the foregoing processors that may manage a data processing request for the data processing system 80 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 84 may include random access memory (RAM), read-only memory (ROM), one or more hard drives, flash memory, or the like. The memory and/or storage circuitry 84 may hold data to be processed by the data processing system 80. In some cases, the memory and/or storage circuitry 84 may also store configuration programs (bit streams) for programming the integrated circuit device 12. The integrated circuit device 12 may be configured to write directly to the memory and/or storage circuitry 84. The network interface 86 may allow the data processing system 80 to communicate with other electronic devices. The data processing system 80 may include several different packages or may be contained within a single package on a single package substrate. For example, components of the data processing system 80 may be located on several different packages at one location (e.g., a data center) or multiple locations. For instance, components of the data processing system 80 may be located in separate geographic locations or areas, such as cities, states, or countries.

In an example, the data processing system 80 may be part of a data center that processes a variety of different requests. For instance, the data processing system 80 may receive a data processing request via the network interface 86 to perform encryption, decryption, machine learning, video processing, voice recognition, image recognition, data compression, database search ranking, bioinformatics, network security pattern identification, spatial navigation, digital signal processing, or some other specialized task.

In the following, some examples of the proposed concept are presented:

An example (e.g., example 1) relates to a Multi-Chip Module, comprising a first chip, a second chip, an interposer substrate to connect the first chip and the second chip, reference circuitry providing a reference for circuitry within at least one of the first chip or the second chip, the reference circuitry comprising at least one passive reference element, and control circuitry for the passive reference element, wherein at least one of the passive reference element or the control circuitry is arranged within the interposer substrate.

Another example (e.g., example 2) relates to a previous example (e.g., example 1) or to any other example, further comprising that the passive reference element comprises a resistance.

Another example (e.g., example 3) relates to a previous example (e.g., one of the examples 1 or 2) or to any other example, further comprising that the passive reference element is arranged within the interposer substrate.

Another example (e.g., example 4) relates to a previous example (e.g., one of the examples 1 to 3) or to any other example, further comprising that the control circuitry is arranged within at least one of the first chip or the second chip.

Another example (e.g., example 5) relates to a previous example (e.g., one of the examples 1 to 3) or to any other example, further comprising that the control circuitry is arranged within the interposer substrate.

Another example (e.g., example 6) relates to a previous example (e.g., one of the examples 1 to 5) or to any other example, wherein the control circuitry comprises at least one of a via or a fuse to enable or disable the at least one passive reference element.

Another example (e.g., example 7) relates to a previous example (e.g., one of the examples 1 to 6) or to any other example, further comprising that the control circuitry is dynamically reconfigurable.

Another example (e.g., example 8) relates to a previous example (e.g., one of the examples 1 to 7) or to any other example, further comprising that the control circuitry comprises at least on switch coupled to the passive reference element.

Another example (e.g., example 9) relates to a previous example (e.g., example 9) or to any other example, further comprising that the control circuitry comprises at least on multiplexer coupled to the switch to control the switch.

Another example (e.g., example 10) relates to a previous example (e.g., example 8) or to any other example, further comprising that the switch is arranged in the first chip or in the second chip.

An example (e.g., example 11) relates to a chip comprising at least one die, reference circuitry providing a reference for circuitry within the die, the reference circuitry comprising at least one resistor assembly comprising at least a first resistance and a second resistance and control circuitry for the passive reference element, wherein at least one of the passive reference element or the control circuitry is arranged within a package substrate of the chip.

Another example (e.g., example 12) relates to a previous example (e.g. example 11) or to any other example, further comprising that the at least on passive reference element is arranged within the package substrate.

Another example (e.g., example 13) relates to a previous example (e.g., example 12) or to any other example, further comprising that the control circuitry is arranged within the die.

Another example (e.g., example 14) relates to a previous example (e.g., one of the examples 11 to 13) or to any other example, further comprising that the control circuitry comprises at least one of a via or a fuse to enable or disable the at least one passive reference element.

Another example (e.g., example 15) relates to a previous example (e.g., one of the examples 11 to 13) or to any other example, further comprising that the control circuitry comprises at least on switch coupled to the passive reference element.

Another example (e.g., example 16) relates to a previous example (e.g., example 15) or to any other example, further comprising that the control circuitry comprises at least on multiplexer coupled to the switch to control the switch.

Another example (e.g., example 17) relates to a previous example (e.g., example 14) or to any other example, further comprising that the control circuitry is arranged at the package substrate.

Another example (e.g., example 18) relates to a previous example (e.g., one of the examples 11 to 17) or to any other example, further comprising that the die implements functionality of a Field-Programmable Gate Array.

Another example (e.g., example 19) relates to configuring the control circuitry to use the at least one passive reference element in a first setting if the first chip and the second chip are used in a first configuration and configuring the control circuitry to use the at least one passive reference element in a second setting if the first chip and the second chip are used in a second configuration.

Another example (e.g., example 20) relates to a previous example (e.g., example 19) or to any other example, further comprising that configuring the control circuitry for the second configuration comprises reconfiguring only the use of a subset of passive reference elements that are required to provide different reference values in the second configuration, while remaining passive reference elements remain unaltered.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not explicitly defined as dependent on that other independent claim.

What is claimed is:

1. A Multi-Chip Module, comprising:
a first chip;
a second chip;
an interposer substrate to connect the first chip and the second chip;
reference circuitry providing a reference for circuitry within at least one of the first chip or the second chip, the reference circuitry comprising:
at least one passive reference element; and
control circuitry for the passive reference element; wherein at least one of the passive reference element or the control circuitry is arranged at the interposer substrate.

2. The Multi-Chip Module of claim 1, wherein the passive reference element comprises a resistance.

3. The Multi-Chip Module of claim 1, wherein the passive reference element is arranged at the interposer substrate.

4. The Multi-Chip Module of any of claim 1, wherein the control circuitry is arranged at at least one of the first chip or the second chip.

5. The Multi-Chip Module of any of claim 1, wherein the control circuitry is arranged at the interposer substrate.

6. The Multi-Chip Module of claim 1, wherein the control circuitry comprises at least one of a via or a fuse to enable or disable the at least one passive reference element.

7. The Multi-Chip Module of claim 1, wherein the control circuitry is dynamically reconfigurable.

8. The Multi-Chip Module of claim 1, wherein the control circuitry comprises at least one switch coupled to the passive reference element.

9. The Multi-Chip Module of claim 1, wherein the control circuitry comprises at least one multiplexer coupled to the switch to control the switch.

10. The Multi-Chip Module of claim 1, wherein the switch is arranged within the first chip or within the second chip.

11. A chip comprising:
at least one die;
reference circuitry providing a reference for circuitry within the die, the reference circuitry comprising:
at least one resistor assembly comprising at least a first resistance and a second resistance; and
control circuitry for the resistor assembly; wherein
at least one of the resistor assembly or the control circuitry is arranged at a package substrate of the chip.

12. The chip of claim 11, wherein the at least one resistor assembly is arranged at the package substrate.

13. The chip of claim 11, wherein the control circuitry is arranged within the die.

14. The chip of claim 11, wherein the control circuitry comprises at least one of a via or a fuse to enable or disable the at least one passive reference element.

15. The chip of claim 11, wherein the control circuitry comprises at least one switch coupled to the passive reference element.

16. The chip of claim 11, wherein the control circuitry comprises at least one multiplexer coupled to the switch to control the switch.

17. The chip of claim 11, wherein the control circuitry is arranged at the package substrate.

18. The chip of claim 11, wherein the die implements functionality of a Field-Programmable Gate Array.

19. A method to operate a multi-chip module comprising a first chip, a second chip, an interposer substrate to connect the first chip and the second chip, reference circuitry providing a reference for circuitry within at least one of the first chip or the second chip, the reference circuitry comprising, at least one passive reference element; and control circuitry for the passive reference element; wherein at least one of the passive reference element or the control circuitry is arranged at the interposer substrate, the method comprising:
configuring the control circuitry to use the at least one passive reference element in a first setting to provide a first reference value if the first chip and the second chip are used in a first operational configuration; and
configuring the control circuitry to use the at least one passive reference element in a second setting to provide a second reference value, different from the first reference value, if the first chip and the second chip are used in a second operational configuration, different from the first operational configuration.

20. The method of claim 19, wherein the at least one passive reference element comprises a plurality of passive reference elements, and wherein configuring the control circuitry for the second operational configuration comprises reconfiguring only the use of a subset of the plurality of passive reference elements that are required to provide different reference values in the second operational configuration, while remaining passive reference elements remain unaltered.
